(19) United States
(12) Patent Application Publication
(10) Pub. No.: US 2004/0188240 A1
(43) Pub. Date: Sep. 30, 2004

(54) Process for in-situ nitridation of salicides

(75) Inventors: Chih-Wei Chang, Hsin-Chu (TW); Mei-Yun Wang, Hsin-Chu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/402,540

(22) Filed: Mar. 28, 2003

(51) Int. Cl. C23C 14/32; C23C 16/00

(52) U.S. Cl. 204/192.12; 427/576; 118/723 I; 118/723 IR; 204/298.07; 204/192.17

(57) ABSTRACT

Novel processes for the in-situ nitridation of metal layers particularly for the subsequent formation of metal salicides. In one embodiment, the nitridation process comprises connecting a remote plasma generator to a rapid thermal processing (RTP) chamber and introducing nitrogen plasma into the chamber as the metal layer is converted into a nitridated metal salicide layer in gate regions on a substrate. In a second embodiment, a remote plasma generator is connected to a physical vapor deposition (PVD) chamber and nitrogen plasma is introduced into the chamber during metal sputter formation of the metal layer. In a third embodiment, the metal layer is first deposited on the silicon or polysilicon and then nitrided using a decoupled plasma nitridation (DPN) process. The metal salicide is formed by subjecting the nitridated metal salicide to a thermal anneal process.

### FIELD OF THE INVENTION

The present invention relates to salicides formed on semiconductor substrates and more particularly, to a process for in-situ nitridation of metal salicides to improve thermal stability and inhibit agglomeration of the salicides.

### BACKGROUND OF THE INVENTION

In the fabrication of semiconductors, advanced lithography and etching processes have facilitated synthesis of integrated circuit devices with ever-decreasing dimensions and increasing integration densities. These scaled-down integrated circuits have higher processing speeds than their larger predecessors. However, this reduction in dimensions has caused a corresponding decrease in the cross-sectional area of the interconnect regions of the circuits, thus leading to an increase in sheet resistance and interconnection time delay. Approaches made in IC manufacturing to decrease the interconnection time delay includes formation of a metal silicide layer on the top of a doped polycrystalline silicon, or polysilicon, in order to lower the sheet resistance of the polysilicon interconnections and thus, facilitate increased circuit speed. A refractory metal silicide that has been reacted with the polysilicon is known as a polycide.

A polycide process is carried out by initially depositing an amorphous silicide conductor, such as nickel or cobalt, on unpatterned doped polysilicon on the wafer substrate. An insulating layer is then deposited on the polycide, and the wafer is patterned and heated to form a crystalline polycide having low resistivity. After insulating sidewall spacers are deposited in the gate region, the source and drain regions are silicided.

FIG. 1 schematically illustrates a polysilicon gate 20 formed between a source 16 and a drain 18 of a device 30 on a semiconductor wafer substrate 10. A shallow trench 12 filled with oxide 14 separates devices from each other on the wafer substrate 10. A polysilicon silicide, or polycide 22, typically composed of nickel or cobalt, is deposited on the polysilicon gate 20, and an insulating layer 28 is deposited on the polycide 22. A source silicide 24 is deposited on the source 16, and a drain silicide 26 is deposited on the drain 18.

As the device features on a wafer decrease in size, the junction between the source and drain regions on the wafer decreases as well, and this requires that a self-aligned silicide, or “salicide”, be used to reduce both the source/drain resistance and the gate resistance. In a salicide process, a metal is deposited over and reacts with the exposed silicon in the source and drain regions and the polysilicon in the gate region to form a silicide. The unreacted metal is removed by etching, which leaves the silicides on the respective source and drain regions and the polycide on the polysilicon gate. Since a masking step is not required for etching the unreacted metal from the reacted metal portions, the silicide process is termed, “self-aligned”.

While titanium has been frequently used in the past to form titanium salicide (TiSi₂) in gate regions on substrates, titanium salicide manifests problems as the source/drain junction decreases to widths of less than 2000 angstroms. Because the silicide thickness may be only several hundred angstroms in an ultra-shallow junction, the etch selectivity of TiSi₂ to borophosphosilicate glass (BPSG) may not be high enough for the TiSi₂ source/drain to withstand the contact etch. Moreover, titanium atoms form compounds with boron (B), and this renders PMOS contact resistance very high. Cobalt silicide (CoSi₂) has been found to be a promising metal for forming ultra-shallow junctions in salicide processes, since CoSi₂ has exhibited excellent etch selectivity to BPSG and since cobalt atoms do not form tightly bonded compounds with arsenic (As) and boron (B) atoms.

One of the problems encountered in the formation of silicide gates is agglomeration of the matal silicide during high-temperature annealing at temperatures of greater than approximately 800 degrees C. Agglomeration results when silicon within and under the metal silicide diffuses and coalesces to form large silicon grains which break the continuity of the silicide film. Consequently, a narrow gate constructed with an agglomerated silicide tends to manifest a significant increase in average sheet resistance. In this regard, localized breaks in the film can impart very high resistance if the silicide is completely severed across the width of the line. As such, in high speed circuit applications which require low-resistance silicide conductors, agglomeration can result in performance degradation or total functional failure.

It has been found that doping nitrogen atoms into a polycide can improve silicide thermal stability and reduce S/D junction leakage during subsequent thermal processing of wafers. Current approaches include incorporating the nitrogen into the silicon substrate and polysilicon gate before or after deposition of the metal silicide to retard silicide agglomeration during subsequent RTA (rapid thermal anneal) processes. However, these approaches have been shown to adversely affect device performance and gate oxide integrity (GOI).

U.S. Pat. No. 5,518,958, dated May 21, 1996, to Giewont, et al., describes a process by which conductors are fabricated by forming a layer of doped polysilicon on a semiconductor substrate, forming a nitrogen-enriched conductive layer on the layer of doped polysilicon, wherein nitrogen contained in the nitrogen-enriched conductive layer provides for improved thermal stability thereof, and patterning the nitrogen-enriched conductive layer and layer of doped polysilicon so as to form the conductors.

U.S. Pat. No. 5,536,684, dated Jul. 16, 1996, to Dass, et al., describes a process wherein a refractory metal layer is deposited on a silicon substrate. On top of the refractory metal layer is deposited a group VIII metal layer. Then a first anneal is performed on the silicon substrate in an ambient comprising a nitrogen containing gas. During the first anneal a group VIII metal silicide layer is formed above the silicon substrate and a refractory metal nitride layer is formed above the group VIII metal silicide layer. After the first anneal is completed, the portion of the group VIII metal silicide layer is transformed into an amorphous group VIII metal silicon mixture. Finally, a second anneal is performed on the silicon substrate in a second ambient. During the second anneal an epitaxial group VIII metal silicide layer is formed.

It has been found that nitridation of salicides during formation of salicide layers on polysilicon or silicon films, rather than nitridation of the polysilicon or silicon followed by salicide formation or nitridation following formation of the salicide, provides a salicide which is both thermally stable with less sheet resistance and does not adversely affect device performance or gate oxide integrity (GOI). The process is preferably performed using a remote plasma generator connected directly to a rapid thermal processing chamber or physical vapor deposition chamber, since this facilitates precise control over incorporation of nitrogen into the forming metal salicide layer.

Accordingly, an object of the present invention is to provide a new and improved process for improving thermal stability and inhibiting agglomeration of salicides.

Another object of the present invention is to provide a process for preventing excessive metal oxide formation on a salicide.

Still another object of the present invention is to provide a process for the nitridation of salicides without sacrificing device performance or gate oxide integrity.

Another object of the present invention is to provide novel processes for the nitridation of salicides.

Still another object of the present invention is to provide novel processes for incorporating nitrogen into a metal film during a physical vapor deposition (PVD) process in a PVD chamber.

Yet another object of the present invention is to provide novel processes for incorporating nitrogen into metal layers using remote plasma nitridation (RPN).

A still further object of the present invention is to provide novel processes for nitridation of a metal film using decoupled plasma nitridation (DPN).

Yet another object of the present invention is to provide a novel process for incorporating nitrogen into a metal film by connecting a remote plasma generator to a plasma vapor deposition (PVD) chamber and introducing nitrogen plasma into the PVD chamber during sputter deposition of the metal in the chamber.

A still further object of the present invention is to provide a novel process for incorporating nitrogen into a metal salicide film by connecting a remote plasma generator to a rapid thermal processing (RTP) chamber and introducing nitrogen gas into the RTP chamber during formation of the metal salicide in the chamber.

Yet another object of the present invention is to provide a novel process for the nitridation of a metal film by forming a metal layer on a polysilicon gate and subjecting the metal to a decoupled plasma nitridation process.

### SUMMARY OF THE INVENTION

According to these and other objects and advantages, the present invention comprises novel processes for the in-situ nitridation of metal layers particularly for the subsequent formation of metal salicides. In one embodiment, the nitridation process comprises connecting a remote plasma generator to a rapid thermal processing (RTP) chamber and introducing nitrogen plasma into the chamber as the metal layer is converted into a nitridated metal salicide layer in gate regions on a substrate. In a second embodiment, a remote plasma generator is connected to a physical vapor deposition (PVD) chamber and nitrogen plasma is introduced into the chamber during metal sputter formation of the metal layer. In a third embodiment, the metal layer is first deposited on the silicon or polysilicon and then nitrided using a decoupled plasma nitridation (DPN) process. The metal salicide is formed by subjecting the nitridated metal salicide to a thermal anneal process.

### BRIEF DESCRIPTION OF THE DRAWINGS

The invention will now be described, by way of example, with reference to the accompanying drawings, wherein:

FIG. 1 is a schematic view illustrating a typical standard gate electrode structure or device on a substrate;

FIG. 2A is a schematic view of a silicon wafer substrate suitable for implementation of the present invention;

FIG. 2B is a schematic view illustrating deposition of a gate oxide layer on a silicon wafer substrate according to the process of the present invention;

FIG. 2C is a schematic view illustrating deposition of a nitridated metal layer on a gate oxide layer on a silicon substrate according to the process of the present invention;

FIG. 3 is a schematic view illustrating a remote plasma generator attached to a rapid thermal processing (RTP) chamber in implementation of the present invention;

FIG. 4 is a schematic view illustrating a remote plasma generator attached to a physical vapor deposition (PVD) chamber in implementation of the present invention;

FIG. 5 is a schematic view illustrating a dual plasma source (DPS) chamber in implementation of the present invention;

FIG. 6 is a graph illustrating sheet resistance as a function of line-width, comparing the sheet resistance of nitrogen-devoid salicides with the sheet resistance of salicides nitridated according to the processes of the present invention; and

FIG. 7 is a graph illustrating sheet resistance as a function of processing temperature, comparing the sheet resistance of nitrogen-devoid salicides with the sheet resistance of salicides nitridated according to the processes of the present invention.

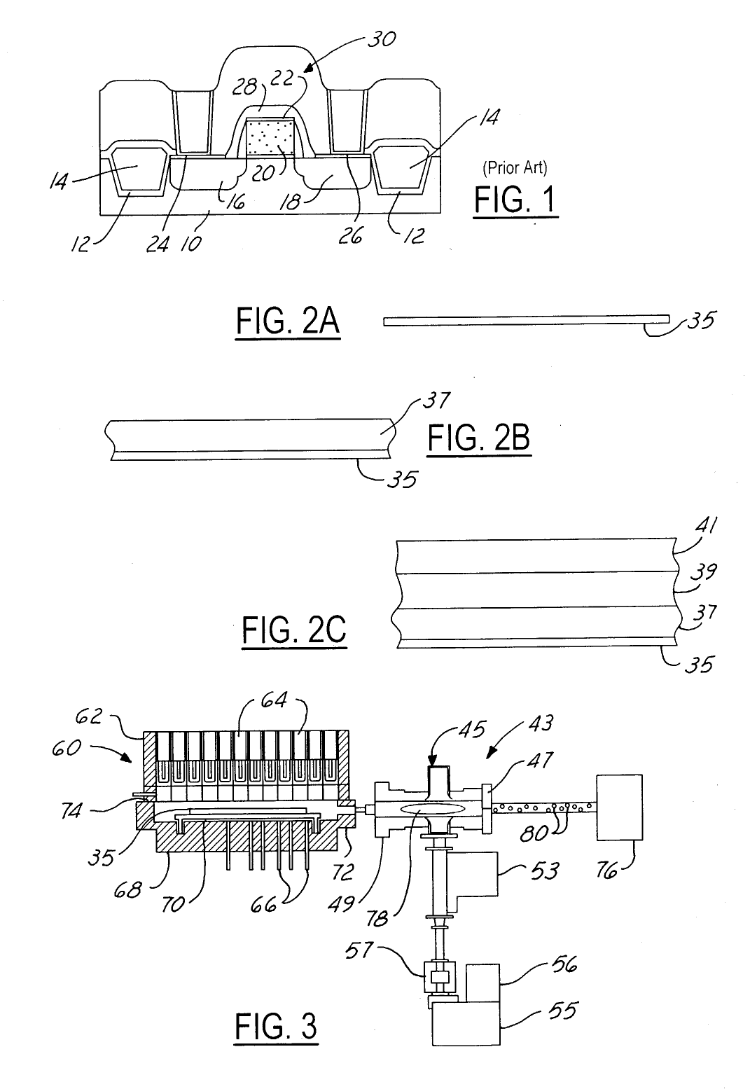

### DESCRIPTION OF THE PREFERRED EMBODIMENTS

Referring initially to FIGS. 2A-2C, fabrication of a gate electrode structure or device including a nitridated salicide on a silicon wafer substrate 35 begins with formation of a gate oxide layer 37 of selected thickness, typically in the range of about 10-100 angstroms, on the substrate 35. Next, a polysilicon layer 39 is formed on the gate oxide layer 37 and typically has a thickness of about 100-200 nm. The gate oxide layer 37 and polysilicon layer 39 may be formed using conventional CVD (chemical vapor deposition) techniques, after which the polysilicon layer 39 may be implanted with ions. The implanted polysilicon layer 39 is next annealed at a temperature of about 900 degrees C., for example, to distribute and activate the dopants therein.

According to a process of the present invention, a nitrogen-enriched metal layer 41 is next deposited on the annealed polysilicon layer 39 as hereinafter further described. Preferably, the nitrogen-enriched metal layer 41 has about 0.5%-15% nitrogen by atomic composition, and the metal used in forming the salicide layer 41 is typically nickel or cobalt. In a first embodiment of the invention, the nitrogen-enriched metal layer 41 is formed by physical vapor deposition and then annealed in a rapid thermal processing (RTP) chamber 60 to convert the metal layer 41 into a metal salicide layer. This is accomplished by initially forming the metal layer 41 on the polysilicon layer 39, using conventional physical vapor deposition process parameters for metal layer formation in an RTP chamber, and then annealing the metal layer 41 in the RTP chamber 60 while simultaneously introducing an argon-nitrogen plasma 78 into the RTP chamber 60 through a remote plasma generator 43. The RTP chamber 60 may be conventional and typically includes a base 68 on which is removably mounted a heater head 62 containing multiple halogen lamps 64. A wafer support 70 is provided inside the RTP chamber 60 and supports the wafer substrate 35 thereon. Optical pyrometers 66 or other temperature-sensing elements extend through the base 68 for measuring the backside temperature of the wafer 35. The base 68 further includes a gas inlet arm 72 for connection with the remote plasma generator 43 and a gas outlet 74 for escape of process gases from the RTP chamber 60.

The remote plasma generator 43 may be conventional and typically includes an applicator 45, having an inlet arm 47 connected to a nitrogen source 76; an outlet arm 49 connected to a gas inlet arm 72 of the RTP chamber 60; a magnetron 55; an isolator 57; and an auto-tuner 53. The magnetron 55 houses a magnetron tube (not shown) which produces microwave energy when supplied with DC power from a DC power supply 56. An antenna (not shown) channels the microwaves from the magnetron 55 to an isolator 57, which absorbs and dissipates reflected power to prevent damage to the magnetron 62. The auto-tuner 53 minimizes the power reflected to the magnetron 62. The applicator 45 of the remote plasma generator 43 is typically water-cooled and is capable of operating continuously at maximum power, and the magnetron 55 of the remote plasma generator 43 generates high frequency (3 kW) microwaves.

Formation of the nitrogen-enriched metal layer 41 is carried out by initially positioning the wafer substrate 35, having had the polysilicon layer 39 (FIG. 2C) previously deposited thereon and the nitrogen-devoid metal film 41 deposited on the polysilicon layer 39 by conventional physical vapor deposition techniques, on the wafer chuck 70 in the RTP chamber 60. Next, as the metal salicide layer is formed from the metal layer 41 in the RTP chamber 60, nitrogen gas 80 is distributed from the nitrogen source 76 and into the applicator 45 of the remote plasma generator 43, which is programmed and operated according to the knowledge of those skilled in the art to generate a nitrogen plasma 78 in the applicator 45. The nitrogen plasma 78 enters the RTP chamber 60, and nitrogen atoms from the nitrogen plasma 78 are embedded in the metal silicide layer 41 as the metal salicide layer 41 is formed on the polysilicon layer 39. The volume of nitrogen gas 80 used to form the nitrogen plasma 78 is selected such that the total nitrogen atom composition in the nitridated metal salicide layer 41 ranges from about 0.5% to about 15% by atomic composition. After formation of the nitrided metal salicide layer 41, conventional process steps may follow to complete the device on the wafer substrate 35.

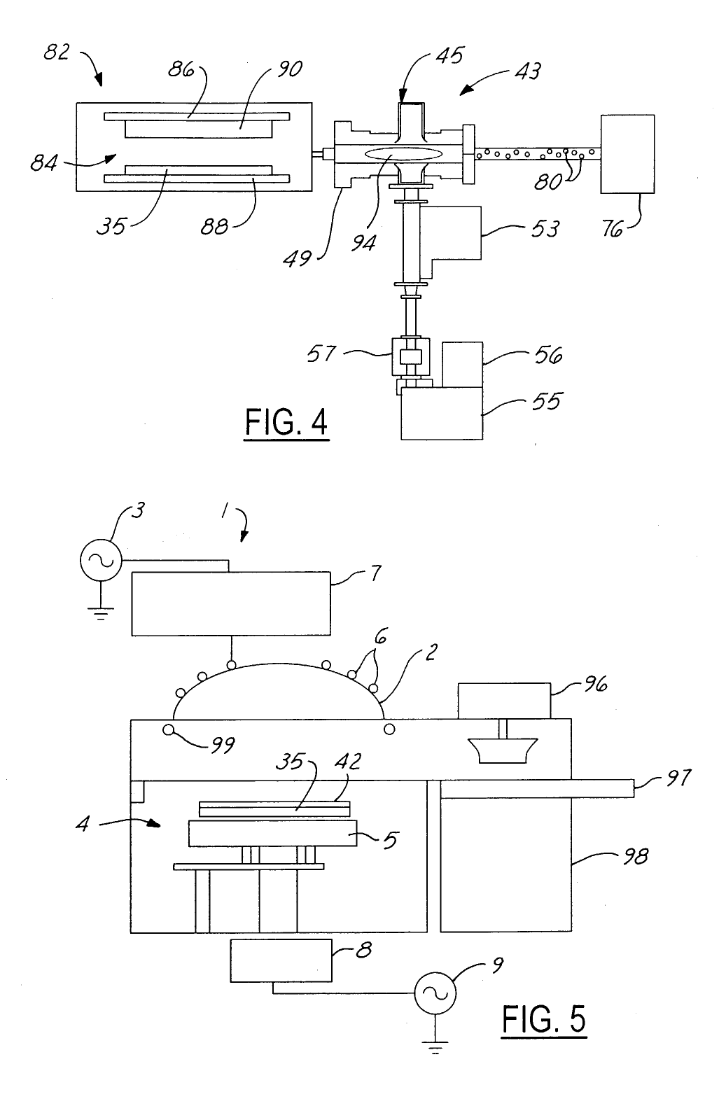

Referring next to FIG. 4, in a second embodiment of the invention, the nitrogen-enriched metal layer 41 (FIG. 2C) is formed on the polysilicon layer 39 using a metal sputtering process in a PVD chamber 82, in conjunction with a remote plasma generator 43 connected to the PVD chamber 82. The PVD chamber 82 may be conventional, and the chamber interior 84 thereof typically contains a cathode 86, an anode 88 and a metal silicate target 90. The wafer substrate 35 is supported on the anode 88. The base chamber of the PVD chamber 82 is typically an Endura PVD chamber.

The remote plasma generator 43 may be conventional and typically includes an applicator 45, having an inlet arm 47 connected to a nitrogen source 76; an outlet arm 49 connected to a gas inlet (not illustrated) in the side of the PVD chamber 82; a magnetron 55; an isolator 57; and an auto-tuner 53. The applicator 45 of the remote plasma generator 43 is typically water-cooled and is capable of operating continuously at maximum power, and the magnetron 55 of the remote plasma generator 43 generates high frequency (3 kW) microwaves.

Argon plasma can be used as the sputter process plasma, and nitrogen gas 80 may be introduced from the nitrogen source 76 into the inlet arm 47 of the applicator 45 through a calibrated mass flow controller (not illustrated). Typical sputtering conditions may include 2220 Watts of DC power at a sputtering plasma pressure of approximately 6 milliTorr and a wafer temperature in the range of about 20 to 25 degrees C., and preferably, about 20 degrees C. Argon gas mixes with nitrogen gas 80 entering the applicator 45 from the nitrogen source 76, and the microwaves generated by the magnetron 55 create an argon-nitrogen sputter process plasma 94 in the applicator 45. A sufficient quantity of the nitrogen gas 80 is mixed with the argon gas in the applicator 45 to form a sputter process plasma 94 sufficient to incorporate between approximately 0.5% and 15%, and preferably, about 0.5% and 10%, of nitrogen by atomic composition in the metal layer 41. After the sputter process plasma 94 exits the outlet arm 49 of the applicator 45 and enters the chamber interior 84, the sputter deposition process then proceeds with bombardment of the metal silicate target 90, with ions from the nitrogen-enriched sputter process plasma 94 displacing molecules from the metal target 90 to deposit the nitrogen-enriched metal layer 41 on the polysilicon layer 39 of the wafer substrate 35. The wafer substrate 35 is typically rotated in the chamber interior 34 throughout the process. After formation of the nitrided metal layer 41, the nitridated metal layer 41 may be annealed in a rapid thermal processing chamber, typically according to conventional process parameters, to convert the metal layer 41 into a metal salicide layer. Conventional process steps may follow to complete the device on the wafer substrate 35.

Referring next to FIG. 5 of the drawings, in a third embodiment the metal layer 41 is nitridated using a DPS (dual plasma source) chamber 1, which may be conventional and typically includes a quasi-remote plasma source 2 located above a chamber interior 4, which is typically a silicon etch DPS (dual plasma source) chamber. Plasma injection openings 99 facilitate 4-point symmetric plasma flow into the chamber interior 4. A cathode 5 is provided in the chamber interior 4 and supports the wafer substrate 35 for nitridation of a nitrogen-devoid metal layer 42 previously deposited on the polysilicon layer 39 typically using a standard PVD process. After processing, as hereinafter described, the nitrogen plasma is evacuated from the chamber interior 4 through a throttle valve 96 and gate valve 97 by operation of a turbo pump 98. An RF source power 3 is connected to an RF match 7 and generates RF energy in the quasi-remote plasma source 2 through inductive coils 6. An RF bias power 9 is connected to a second RF match 8 for applying a voltage bias to the wafer substrate 35, as needed.

In application, the initially nitrogen-devoid metal layer 41 is first formed on the polysilicon layer 39 on the wafer substrate 35 using conventional PVD techniques, tyically using nickel or cobalt as the metal, before the wafer substrate 35 is positioned on the cathode 5 in the chamber interior 4. Typical process conditions include a wafer substrate temperature of less than about 100 degrees C.; source RF power 3 set at 12.56 MHz and 0-2000 Watts; and bias power 9 set at 13.56 MHz and 0-500 Watts. A nitrogen plasma is next generated inside the plasma source 2, and the plasma flows through the plasma injection openings 99 and into the chamber interior 4, where the neutral nitrogen atoms strike and are embedded in the initially nitrogen-devoid nickel or cobalt metal layer 41 to convert the nitrogen-devoid metal layer 41 to the nitridated metal layer 41 having from about 0.5% to about 15% nitrogen by atomic composition. Because the source plasma power 3 is decoupled from the bias power 9, decoupled plasma nitridation of the metal layer 41 according to the process of the present invention permits enhanced control over ion density and ion energy of the nitrogen plasma, resulting in improved control over incorporation of nitrogen into the metal layer. After formation of the nitrided metal layer 41, the nitridated metal layer 41 is annealed in a rapid thermal processing chamber, typically according to conventional process parameters, to convert the metal layer 41 into a metal salicide layer.

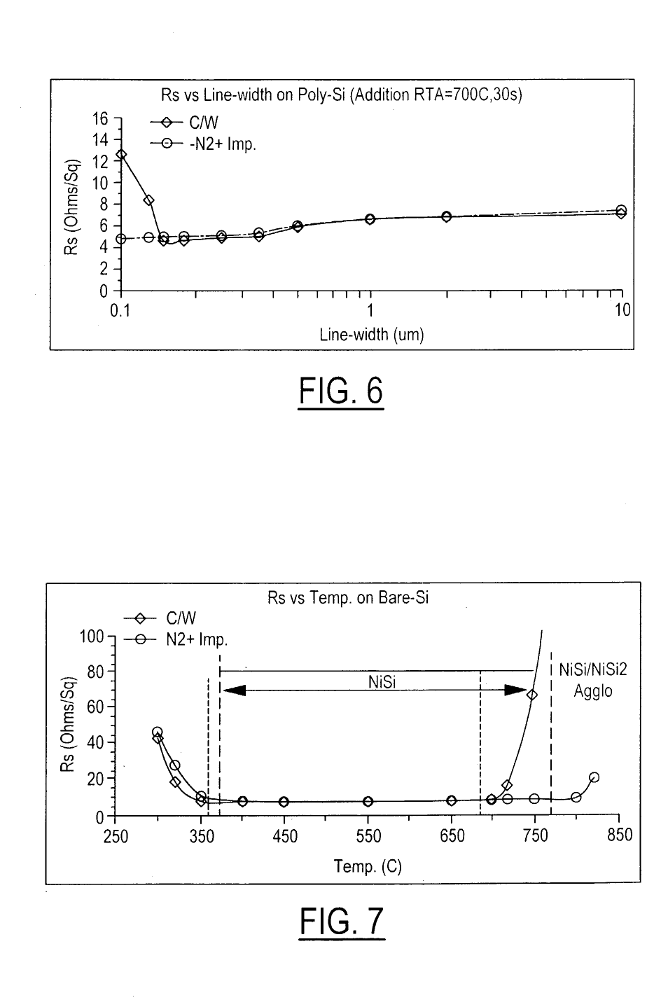

Referring next to FIG. 6, a graph is illustrated wherein sheet resistance is plotted as a function of line width of a salicided polysilicon gate. Nitrogen-devoid salicided polysilicon is indicated by the connected diamonds, whereas polysilicon salicide nitridated according to a process of the present invention is indicated by the connected circles. It can be seen from the graph that nitridation of the salicide according to the process of the present invention substantially reduces sheet resistance at line widths of between 0.1 and about 0.25.

Referring next to FIG. 7, a graph is illustrated wherein sheet resistance is plotted as a function of processing temperature. Nitrogen-devoid salicided polysilicon is indicated by the connected diamonds, whereas polysilicon salicide nitridated according to a process of the present invention is indicated by the connected circles. It can be seen from the graph that nitridation of the salicide according to the process of the present invention substantially enhances thermal stability of the salicide at temperatures exceeding about 700 degrees C., as indicated by the substantially lower sheet resistance of the nitridated salicide as compared to that of the nitrogen-devoid salicide at those temperatures. Thermal stability of the nitridated salicide remains stable up to about 800 degrees C.

While the preferred embodiments of the invention have been described above, it will be recognized and understood that various modifications can be made in the invention and the appended claims are intended to cover all such modifications which may fall within the spirit and scope of the invention.

Having described our invention with the particularity set forth above, we claim:

What is claimed is:

1. A method for incorporating nitrogen into a metal film, comprising the steps of:
providing a process chamber;
providing a substrate in said process chamber;
forming a metal film on said substrate; and
providing a plasma including nitrogen in said process chamber while forming said metal film on said substrate to incorporate said nitrogen into said metal film to define a nitridated metal film.

2. The method of claim 1 wherein said nitridated metal film is about 0.5% to about 15% nitrogen by atomic composition.

3. The method of claim 1 further comprising the steps of providing a remote plasma generator in fluid communication with said process chamber and forming said plasma in said remote plasma generator.

4. The method of claim 3 wherein said nitridated metal film is about 0.5% to about 15% nitrogen by atomic composition.

5. The method of claim 1 wherein said process chamber comprises a physical vapor deposition chamber.

6. The method of claim 5 further comprising the steps of providing a remote plasma generator in fluid communication with said physical vapor deposition chamber and forming said plasma in said remote plasma generator.

7. The method of claim 3 wherein said remote plasma generator comprises a water-cooled applicator.

8. The method of claim 7 wherein said nitridated metal film is about 0.5% to about 15% nitrogen by atomic composition.

9. The method of claim 7 wherein said process chamber comprises a physical vapor deposition chamber.

10. The method of claim 3 wherein said remote plasma generator comprises a 3 kw microwave source.

11. The method of claim 10 wherein said nitridated metal film is about 0.5% to about 15% nitrogen by atomic composition.

12. The method of claim 10 wherein said process chamber comprises a physical vapor deposition chamber.

13. A method for incorporating nitrogen into a metal film, comprising the steps of:
providing a process chamber;
providing a substrate in said process chamber;
forming a metal film on said substrate by subjecting said substrate to a metal sputtering process; and
providing a plasma including nitrogen in said process chamber during said metal sputtering process to incorporate said nitrogen into said metal film to define a nitridated metal film.

14. The method of claim 13 wherein said process chamber comprises a physical vapor deposition chamber.

15. The method of claim 13 further comprising the steps of providing a remote plasma generator in fluid communication with said process chamber and forming said plasma in said remote plasma generator.

16. The method of claim 13 wherein said nitridated metal film is about 0.5% to about 15% nitrogen by atomic composition.

17. A method for incorporating nitrogen into a metal film, comprising the steps of:
providing a substrate;
forming a metal film on said substrate;
providing a dual plasma source chamber;
placing said substrate in said chamber; and
providing a plasma including nitrogen in said chamber to incorporate said nitrogen into said metal film to define a nitridated metal film.

18. The method of claim 17 wherein said nitridated metal film is about 0.5% to about 15% nitrogen by atomic composition.

19. The method of claim 17 wherein said metal film is a metal film selected from the group consisting of nickel film and cobalt film.

20. The method of claim 19 wherein said nitridated metal film is about 0.5% to about 15% nitrogen by atomic composition.

21. An apparatus for forming a nitridated metal film on a substrate, comprising:
a process chamber for receiving the substrate and depositing a metal film on the substrate; and
a remote plasma generator provided in communication with said process chamber for generating a nitrogen plasma and introducing the nitrogen plasma into said process chamber.

22. The apparatus of claim 21 wherein said process chamber comprises a physical vapor deposition chamber.
